(19) United States
(12) Patent Application Publication
(10) Pub. No.: US 2024/0044988 A1
(43) Pub. Date: Feb. 8, 2024

(54) ABNORMALITY DETECTION DEVICE, ABNORMALITY DETECTION METHOD, AND COMPUTER PROGRAM

(71) Applicant: GS Yuasa International Ltd., Kyoto-shi, Kyoto (JP)

(72) Inventors: Kayo YAMASAKI, Kyoto-shi, Kyoto (JP); Isamu KURISAWA, Kyoto-shi, Kyoto (JP); Hitoshi MATSUSHIMA, Kyoto-shi, Kyoto (JP)

(21) Appl. No.: 18/256,147

(22) PCT Filed: Nov. 9, 2021
(86) PCT No.: PCT/JP2021/041168

§ 371 Date: Jun. 6, 2023

(30) Foreign Application Priority Data
Dec. 16, 2020 (JP) 2020-208672

(51) Int. Cl. G01R 31/367

(52) U.S. Cl. CPC G01R 31/367

(57) ABSTRACT

An abnormality detection device includes: a creation unit that creates learning data by statistically processing plural pieces of measurement data, which may include abnormal measurement data, of an energy storage device; a storage unit that stores a model learned to output a score corresponding to whether or not abnormal measurement data is included in the measurement data when the measurement data is input using the created learning data; and a detection unit that detects an abnormality or a sign of abnormality of the energy storage device based on the score output by inputting the plurality of pieces of measurement data to the model.

### CROSS REFERENCE TO RELATED APPLICATIONS

This application is a National Stage Application, filed under 35 U.S.C. § 371, of International Application No. PCT/JP2021/041168, filed Nov. 9, 2021, which international application claims priority to and the benefit of Japanese Application No. 2020-208672, filed Dec. 16, 2020; the contents of both of which are hereby incorporated by reference in their entirety.

### BACKGROUND

### Technical Field

The present invention relates to an abnormality detection device, an abnormality detection method, and a computer program for detecting an abnormality based on measurement data of an energy storage device.

### Description of Related Art

An energy storage device is widely used in an uninterruptible power system, a DC or AC power supply device included in a stabilized power supply, and the like. Further, the use of energy storage devices in large-scale systems that store renewable energy or power generated by existing power generating systems is expanding.

In a system using an energy storage device, it is necessary to detect a state of the energy storage device. Patent Document 1 discloses use of a model for determining safety or abnormality of an energy storage device. In Patent Document JP-A-2017-092028, data determined to be normal is acquired in advance, and the model is created by machine learning such as deep learning based on the acquired data.

### BRIEF SUMMARY

The model for abnormality detection is machine-learned using learning data in which data of a normal product and data of a non-normal product (abnormal product) are classified in advance. However, it is not easy to prepare the learning data including the classification as to whether or not it is normal product data for the energy storage device.

An object of the present invention is to provide an abnormality detection device, an abnormality detection method, and a computer program for detecting an abnormality or a sign thereof based on measurement data of an energy storage device.

An abnormality detection device includes: a creation unit that creates learning data by statistically processing plural pieces of measurement data, which may include abnormal measurement data, of an energy storage device; a storage unit that stores a model learned to output a score corresponding to whether or not abnormal measurement data is included in the measurement data when the measurement data is input using the created learning data; and a detection unit that detects an abnormality or a sign of abnormality of the energy storage device based on the score output by inputting the plural pieces of measurement data to the model.

### BRIEF DESCRIPTION OF THE FIGURES

FIG. 1 is a diagram showing an outline of a remote monitoring system.

FIG. 2 is a diagram showing an example of a hierarchical structure of energy storage module groups and a connection form of a communication device.

FIG. 3 is a block diagram showing internal configurations of devices included in the remote monitoring system.

FIG. 4 is a block diagram showing the internal configurations of the devices included in the remote monitoring system.

FIG. 5 is a flowchart showing an example of a processing procedure of model creation and storage by a server device.

FIG. 6 is an explanatory diagram of a read target period and a detection target period.

FIG. 7 is a schematic diagram of an example of a model to be created.

FIG. 8 is a schematic diagram of learning data creation.

FIG. 9 is a flowchart showing an example of an abnormality detection processing procedure by the server device.

FIG. 10 is a graph schematically showing a time distribution of measurement data of plural energy storage cells.

FIG. 11 shows an application range of an abnormality detection method.

FIG. 12 shows an example of a state screen displayed on a client device.

### DETAILED DESCRIPTION OF VARIOUS EMBODIMENTS

An abnormality detection device includes: a creation unit that creates learning data by statistically processing plural pieces of measurement data, which may include abnormal measurement data, of an energy storage device; a storage unit that stores a model learned to output a score corresponding to whether or not abnormal measurement data is included in the measurement data when the measurement data is input using the created learning data; and a detection unit that detects an abnormality or a sign of abnormality of the energy storage device based on the score output by inputting the plural pieces of measurement data to the model.

Here, the “plural pieces of measurement data which may include abnormal measurement data” means plural pieces of measurement data in which measurement data to be determined to be abnormal or heterogeneous is not completely artificially or mechanically excluded.

The meaning of the “plural pieces of measurement data which may include abnormal measurement data” includes plural pieces of measurement data in which measurement data to be determined to be abnormal or heterogeneous is not artificially or mechanically excluded at all.

The meaning of the “plural pieces of measurement data which may include abnormal measurement data” also includes plural pieces of measurement data obtained by artificially or mechanically excluding a part (for example, extreme outliers) of measurement data to be determined to be abnormal or heterogeneous.

The meaning of the “plural pieces of measurement data which may include abnormal measurement data” includes measurement data which does not actually include abnormal measurement data (measurement data which is not subjected to processing of artificially or mechanically excluding abnormal measurement data) because the energy storage device is new or the state of the energy storage device is good.

The score may be a numerical value or a classification output from a model subjected to unsupervised learning. The score may be, for example, a reconstruction error obtained from an auto encoder. Alternatively, the score may be a numerical value or a classification output from a model subjected to learning. It tends to be difficult to prepare appropriate learning data by preparing measurement data of another system operated under the same conditions as the energy storage system actually operated or by a virtual method such as simulation. Therefore, it is preferable to adopt unsupervised learning capable of analyzing characteristics of measurement data of the energy storage system actually operated.

With the above configuration, in order to prepare the learning data from the measurement data obtained with the operation, it is not necessary to separate the data to be determined to be normal and the data to be determined to be abnormal (the trouble for data selection is eliminated). The preparation work of the learning data is simplified, and a part or all of the preparation work can be automated.

In the measurement data indicating the state of the energy storage device (or indirectly indicating the state of the system surrounding the energy storage device), the characteristics may change depending on the aged deterioration and the use environment of the energy storage device. The current measurement data of the energy storage device and the measurement data after several months or years are different from each other even when the energy storage device is operated in the same charge-discharge pattern. The energy storage device deteriorates depending on a use period and a use environment, and the measurement data inevitably changes little by little. Among them, it is difficult to distinguish whether or not the obtained measurement data is abnormal data using a mathematical model or a threshold. It is necessary to perform very complicated work to accurately separate abnormality/normality and prepare learning data. On the other hand, as in the above configuration, by “creating learning data by statistically processing plural pieces of measurement data of an energy storage device, the plural pieces of measurement data that may include abnormal measurement data”, complicated work can be unnecessary or simplified.

In the abnormality detection of the measurement data acquired after the start of the operation using the model learned from the measurement data acquired before the start of the operation or at the beginning of the operation of the energy storage device, there is a possibility that the measurement data which is not abnormal is erroneously detected as an abnormality or a sign thereof. For example, when the model is learned using the measurement data acquired at the beginning of the operation as data of a normal product, the model detects a change in the characteristics of the energy storage device due to a simple secular change in the characteristics of the energy storage device or a change in the operation environment (a seasonal change or a change in the degree of charge-discharge) as an abnormality or a sign thereof. This is called deterioration diagnosis and is not abnormality detection.

In the abnormality detection device having the above configuration, the measurement data used for learning the model is the measurement data to be subjected to the abnormality detection. According to the above configuration, there is no influence (or little influence) due to the difference in the period or the operation environment between the time of learning the model and the time of abnormality detection using the model.

When the model is simply learned as data of a normal product including abnormal measurement data, the learned model cannot detect the abnormal measurement data as an abnormality or a sign thereof at the time of detection. As in the above configuration, the present inventors have found that by statistically processing plural pieces of measurement data that may include abnormal measurement data, appropriate learning data can be easily prepared and model learning can be executed. In the abnormality detection device having the above configuration, the additional learning of the model and the reconstruction of the model can be relatively easily realized.

The learning data used for learning the model by the abnormality detection device may be created using an average of the plural pieces of measurement data which may include abnormal measurement data of the energy storage device.

The present inventors have found that pseudo normal data (learning data) can be obtained using an average of plural pieces of measurement data which may include abnormal measurement data of the energy storage device. In an actual energy storage system, the occurrence of abnormality of the energy storage device and system failure is extremely small. The inventors of the present invention have found that a small number of pieces of abnormal data included in a large number of pieces of measurement data is appropriately rounded by averaging so as not to negatively affect learning of a model for abnormality detection of the energy storage device. Rather, the present inventors have found that appropriate learning data can be prepared from data in which normal and abnormal (or heterogeneous) are mixed. The learning data thus obtained is suitably applied to, for example, learning of an auto encoder.

The energy storage device may be configured by connecting plural modules including plural energy storage cells in series. The creation unit may create the learning data by averaging measurement data of energy storage cells of same order in the plurality of modules.

The energy storage device may have a configuration (also referred to as a domain) in which plural configurations (also referred to as banks) in which plural modules including plural energy storage cells are connected in series are connected in parallel. The creation unit may create the learning data by averaging measurement data of energy storage cells of same order in the plurality of modules included in the domain.

In this manner, appropriate learning data can be created by the average calculation method in consideration of the configuration of the energy storage device.

In the abnormality detection device, the creation unit may create the learning data from measurement data read for a read target period among measurement data measured in time series from the energy storage device. The detection unit may input, to a model learned by the learning data, measurement data in a detection target period that is a same period as the read target period, and detect an abnormality or a sign of abnormality of the energy storage device in the detection target period based on a score output from the model.

With the above configuration, it is possible to eliminate the influence of the difference in the period or environment between the time of learning the model and the time of abnormality detection using the model by sequentially reconstructing the model.

In the abnormality detection device, the creation unit may create the learning data from measurement data read for a read target period among measurement data measured in time series from the energy storage device. The detection unit may input, to a model learned by the learning data, measurement data in a detection target period partially overlapping the read target period, and detect an abnormality or a sign of abnormality of the energy storage device in the detection target period based on a score output from the model.

When the fluctuation of the measurement data is small, it is not always necessary to make the learning period and the detection period the same, and the abnormality detection may be performed using a model learned from measurement data slightly before. When measurement data cannot be sufficiently acquired, for example, when the energy storage system is stopped, it is possible to detect an abnormality even by using a model learned from measurement data slightly before.

An abnormality detection method includes: creating learning data by statistically processing plural pieces of measurement data of an energy storage device, the plural pieces of measurement data that may include abnormal measurement data; learning a model to output a score corresponding to whether or not abnormal measurement data is included in the measurement data when the measurement data is input using the created learning data; storing the learned model; and detecting an abnormality or a sign of abnormality of the energy storage device based on a score output by inputting the plural pieces of measurement data to the model.

The abnormality detection method may be performed using a computer installed close to the energy storage device, or may be performed using a computer installed remotely.

A computer program causes a computer to execute processes of: creating learning data by statistically processing plural pieces of measurement data of an energy storage device, the plural pieces of measurement data that may include abnormal measurement data; learning a model to output a score corresponding to whether or not abnormal measurement data is included in the measurement data when the measurement data is input using the created learning data; storing the learned model; and detecting an abnormality or a sign of abnormality of the energy storage device based on a score output by inputting the plural pieces of measurement data to the model.

The computer program may be executed by a computer installed close to the energy storage device or may be executed by a computer installed remotely.

The present invention will be specifically described with reference to the drawings showing an embodiment thereof.

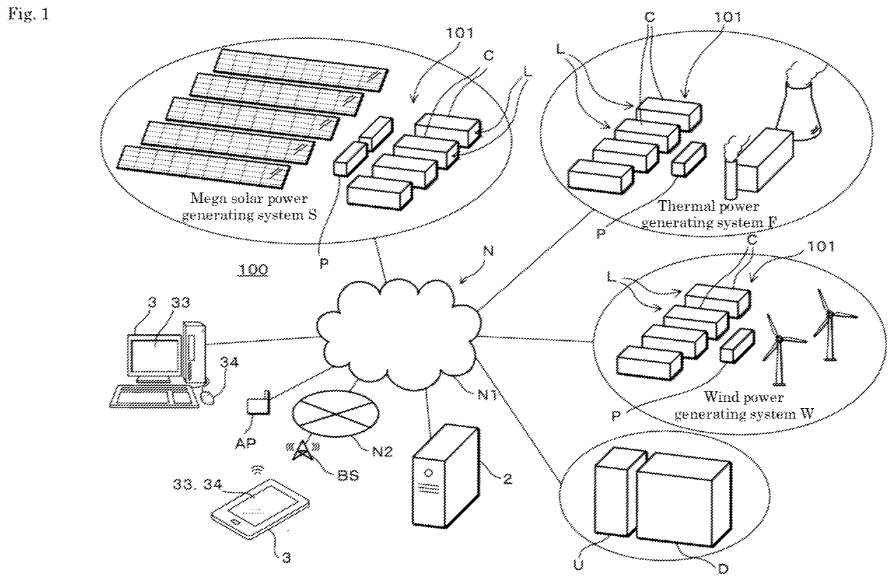

FIG. 1 is a diagram showing an outline of a remote monitoring system 100. The remote monitoring system 100 enables remote access to information on energy storage devices and power supply related devices included in a mega solar power generating system S, a thermal power generating system F, and a wind power generating system W. An uninterruptible power system (UPS) U and a rectifier (d.c. power supply or a.c. power supply) D disposed in a stabilized power supply system for a railway or the like may be remotely monitored.

A power conditioning system (PCS) P and an energy storage system (ESS) 101 are provided in parallel in each of the mega solar power generating system S, the thermal power generating system F, and the wind power generating system W. The energy storage system 101 may be configured by arranging plural containers C each accommodating an energy storage module group L in parallel. Alternatively, the energy storage module groups L and the power conditioner P may be disposed in a building (energy storage room). The energy storage module group L includes plural energy storage devices. The energy storage devices are preferably secondary batteries such as lead-acid batteries or lithium ion batteries or capacitors, which are rechargeable. Some of the energy storage devices may be a non-rechargeable primary battery.

In the remote monitoring system 100, a communication device 1 is mounted on/connected to each of the energy storage systems 101 or devices (P, U, D and management devices M to be described later) in the systems S, F, and W to be monitored. The remote monitoring system 100 includes the communication devices 1, a server device 2 (abnormality detection device) that collects information from the communication devices 1, a client device 3 for browsing the collected information, and a network N that is a communication medium between the devices.

The communication device 1 may be a terminal device (measurement monitor) that communicates with a battery management unit (BMU) included in the energy storage device to receive information of the energy storage device, or may be a controller compatible with ECHONET/ECHONET Lite (registered trademark). The communication device 1 may be an independent device or a network card type device that can be mounted on the power conditioner P or the energy storage module group L. The communication device 1 is provided for each group including plural energy storage modules in order to acquire information of the energy storage module group L in the energy storage system 101. A plurality of the power conditioners P are connected so as to be able to perform serial communication, and the communication device 1 is connected to a control unit of one of the representative power conditioners P.

The server device 2 has a web server function, and presents information obtained from the communication device 1 mounted on/connected to each device to be monitored according to access from the client device 3.

The network N includes a public communication network N1 that is a so-called Internet and a carrier network N2 that realizes wireless communication according to a predetermined mobile communication standard. The public communication network N1 includes a general optical line, and the network N includes a dedicated line connected to the server device 2. The network N may include a network compatible with ECHONET/ECHONET Lite. The carrier network N2 includes a base station BS, and the client device 3 can communicate with the server device 2 from the base station BS via the network N. An access point AP is connected to the public communication network N1, and the client device 3 can transmit and receive information from the access point AP to and from the server device 2 via the network N.

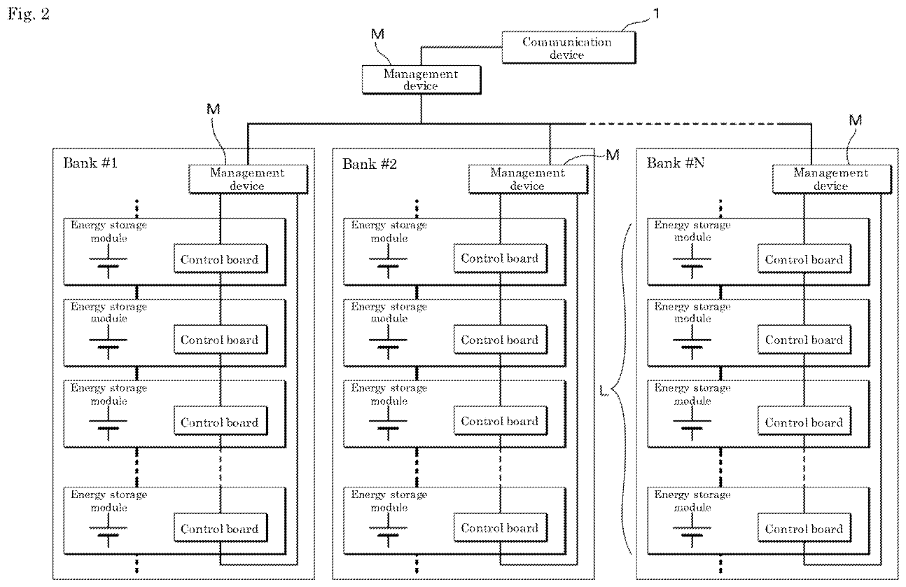

The energy storage module groups L of the energy storage system 101 have a hierarchical structure. The communication device 1 that transmits the information of the energy storage devices to the server device 2 acquires the information of the energy storage module group from the management device M provided in the energy storage module group L. FIG. 2 is a diagram showing an example of a hierarchical structure of the energy storage module groups L and a connection form of the communication device 1. The energy storage module group L has a hierarchical structure including, for example, energy storage modules (also referred to as modules) in which plural energy storage cells (also referred to as cells) are connected in series, a bank in which plural energy storage modules are connected in series, and a domain in which plural banks are connected in parallel. In the example of FIG. 2, one management device M is provided for each of the banks numbered (#) 1 to N and the domain in which the banks are connected in parallel. The management device M provided for each bank communicates with a control board (cell management unit (CMU)) with a communication function built in each energy storage module by serial communication, and acquires measurement data (current, voltage, temperature) for the energy storage cells in the energy storage module. The management device M for a bank executes management processing such as detection of an abnormality in the communication state. Each of the management devices M for a bank transmits measurement data obtained from the energy storage modules of each bank to the management device M provided in the domain. The management device M for a domain aggregates information such as measurement data obtained from the management devices M for a bank belonging to the domain and detected abnormality. In the example of FIG. 2, the communication device 1 is connected to the management device M for a domain. Alternatively, the communication device 1 may be connected to each of the management device M for a domain and the management devices M for a bank. The management device M can acquire identification data (identification number) of a domain or a bank of a device to which the management device M is connected.

In one example, the hierarchical structure of the energy storage system 101 includes twelve banks in which twelve power storage modules configured by connecting twelve energy storage cells in series are connected in series (domain). In one example, the energy storage system 101 may include two domains, in which case the energy storage system 101 includes three thousand four hundred and fifty-six energy storage cells. As another example, the energy storage system 101 has a hierarchical structure including plural banks in which sixteen power storage modules configured by connecting eighteen energy storage cells in series are connected in series. The hierarchical structure of the energy storage system 101 is not limited thereto.

The energy storage system 101 may include a single bank instead of the configuration shown in FIG. 2 in which a plurality of banks are connected in parallel.

In remote monitoring system 100, in the large-scale ESS as described above, the server device (abnormality detection device) 2 collects data such as SOC (State Of Charge) and SOH (State Of Health) in the energy storage system 101 using communication device 1 mounted on each apparatus. The server device 2 processes the collected data, detects the state of the energy storage system 101, and presents the state to the user via the client device 3.

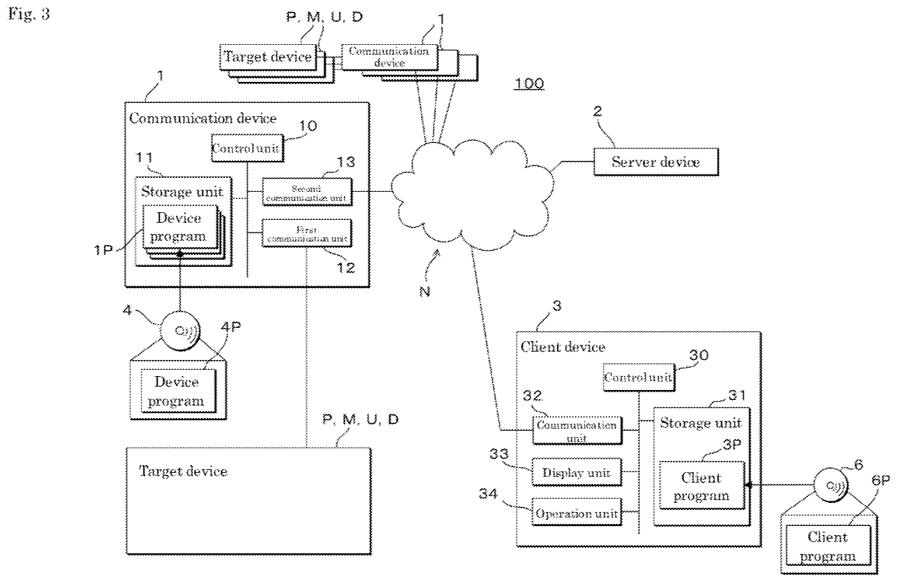

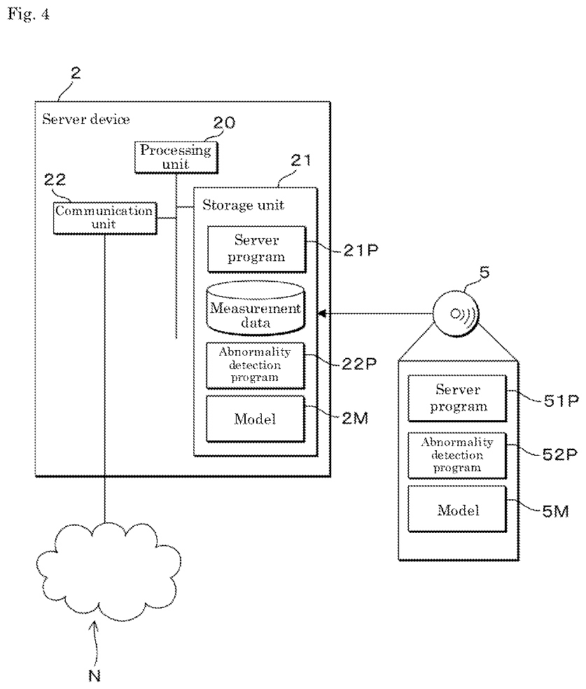

FIGS. 3 and 4 are block diagrams showing internal configurations of devices included in the remote monitoring system 100. As shown in FIG. 3, the communication device 1 includes a control unit 10, a storage unit 11, a first communication unit 12, and a second communication unit 13. The control unit 10 is a processor using a central processing unit (CPU), and executes processing by controlling each component using built-in memories such as a read only memory (ROM) and a random access memory (RAM).

The storage unit 11 uses a non-volatile memory such as a flash memory. The storage unit 11 stores a device program read and executed by the control unit 10. A device program 1P includes a communication program conforming to Secure Shell (SSH), Simple Network Management Protocol (SNMP), or the like. The storage unit 11 stores information such as information collected by the processing of the control unit 10 and an event log. The information stored in the storage unit 11 can also be read via a communication interface such as a USB whose terminal is exposed to a housing of the communication device 1.

The first communication unit 12 is a communication interface that realizes communication with a monitoring target device to which the communication device 1 is connected. The first communication unit 12 uses, for example, a serial communication interface such as an RS-232C or an RS-485. For example, the power conditioner P includes a control unit having a serial communication function conforming to the RS-485, and the first communication unit 12 communicates with the control unit. When the control boards included in the energy storage module group L are connected by a controller area network (CAN) bus and communication between the control boards is realized by CAN communication, the first communication unit 12 is a communication interface based on a CAN protocol. The first communication unit 12 may be a communication interface compatible with the ECHONET/ECHONET Lite standard.

The second communication unit 13 is an interface that realizes communication via the network N, and uses, for example, Ethernet (registered trademark) or a communication interface such as a wireless communication antenna. The control unit 10 is communicably connectable to the server device 2 via the second communication unit 13. The second communication unit 13 may be a communication interface compatible with the ECHONET/ECHONET Lite standard.

In the communication device 1 configured as described above, the control unit 10 acquires, via the first communication unit 12, measurement data for the energy storage devices obtained in the device to which the communication device 1 is connected. The control unit 10 may function as an SNMP agent and respond to an information request from the server device 2 by reading and executing an SNMP program.

The client device 3 is a computer used by an operator such as an administrator or a person in charge of maintenance of the energy storage system 101 each of the power generating systems S, F, and W. The client device 3 may be a desktop or laptop personal computer, or a so-called smartphone or a tablet communication terminal. The client device 3 includes a control unit 30, a storage unit 31, a communication unit 32, a display unit 33, and an operation unit 34.

The control unit 30 is a processor using a CPU. The control unit 30 causes the display unit 33 to display a web page provided by the server device 2 or the communication device 1 based on a client program 3P including a web browser stored in the storage unit 31.

The storage unit 31 uses, for example, a non-volatile memory such as a hard disk or a flash memory. The storage unit 31 stores various programs including the client program 3P. The client program 3P may be obtained by reading a client program 6P stored in a recording medium 6 and copying the client program 6P to the storage unit 31.

The communication unit 32 uses a communication device such as a network card for wired communication, a wireless communication device for mobile communication connected to the base station BS (see FIG. 1), or a wireless communication device compatible with connection to the access point AP. The control unit 30 can perform communication connection or transmission and reception of information with the server device 2 or the communication device 1 via the network N by the communication unit 32.

As the display unit 33, a display such as a liquid crystal display or an organic electro luminescence (EL) display is used. The display unit 33 displays an image of a web page provided by the server device 2 or the communication device 1 by processing based on the client program 3P of the control unit 30. The display unit 33 is preferably a touch panel built-in display, but may be a touch panel non-built-in display.

The operation unit 34 is a keyboard and a pointing device capable of inputting and outputting to and from the control unit 30, or a user interface such as a sound input unit. The operation unit 34 may use a touch panel of the display unit 33 or a physical button provided on a housing. The operation unit 34 notifies the control unit 30 of operation information by the user.

As shown in FIG. 4, the server device (abnormality detection device) 2 uses a server computer, and includes a processing unit 20, a storage unit 21, and a communication unit 22. In the present embodiment, the server device 2 will be described as one server computer, but processing may be distributed among a plurality of server computers.

The processing unit 20 is a processor using a CPU or a graphics processing unit (GPU), and executes processing by controlling each component using a built-in memory such as a ROM and a RAM. The processing unit 20 executes communication and information processing based on a server program 21P stored in the storage unit 21. The server program 21P includes a web server program, and the processing unit 20 functions as a web server that executes provision of a web page to the client device 3. The processing unit 20 collects information from the communication device 1 as an SNMP server based on the server program 21P. The processing unit 20 executes abnormality detection processing based on measurement data collected based on an abnormality detection program 22P stored in the storage unit 21.

The storage unit 21 uses, for example, a non-volatile memory such as a hard disk or a flash memory. The storage unit 21 stores the server program 21P described above and an abnormality detection program 22P. The storage unit 21 stores a model 2M used in processing based on the abnormality detection program 22P. The storage unit 21 stores measurement data of the power conditioners P and the energy storage module groups L of the energy storage system 101 to be monitored collected by the processing of the processing unit 20.

The server program 21P, the abnormality detection program 22P, and the model 2M stored in the storage unit 21 may be obtained by reading a server program 51P, an abnormality detection program 52P, and a model 5M stored in the recording medium 5 and copying them to the storage unit 21.

The communication unit 22 is a communication device that realizes communication connection and transmission and reception of information via the network N. Specifically, the communication unit 22 is a network card compatible with the network N.

In the remote monitoring system 100 configured as described above, the communication device 1 transmits the measurement data of each energy storage cell acquired from the management device M after the previous timing to the server device 2 at each predetermined timing. The predetermined timing may be, for example, a constant period or a case where the data amount satisfies a predetermined condition. The communication device 1 may transmit all the measurement data obtained via the management device M, may transmit the measurement data thinned out at a predetermined ratio, or may transmit an average value of the measurement data. The server device 2 acquires information including the measurement data from the communication device 1, and stores the acquired measurement data in the storage unit 21 in association with the acquisition time information and information for identifying a device (M, P) as an acquisition destination of the information.

The server device 2 can present the stored latest data of the energy storage system 101 according to the access from the client device 3. The server device 2 can present a state of each energy storage cell, each power storage module, bank, or domain. The server device 2 can perform abnormality diagnosis, deterioration diagnosis, estimation of SOC, SOH, or the like, or life prediction of the energy storage system 101 using the measurement data, and present an implementation result.

Based on the abnormality detection program 22P and the model 2M shown in FIG. 4, the server device 2 individually determines whether the energy storage cell is abnormal or has a sign of the abnormality from the measurement data of the energy storage cell. The server device 2 performs state detection for each power storage module, bank, or domain based on the determination result.

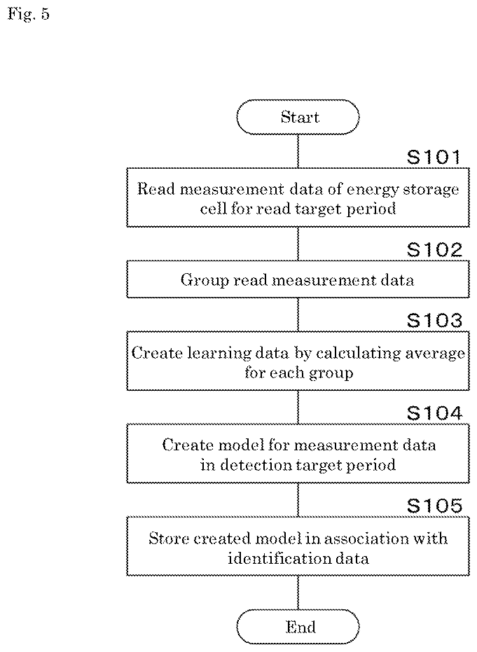

FIG. 5 is a flowchart showing an example of a processing procedure of model creation and storage by the server device 2. The processing unit 20 of the server device 2 periodically executes the following processing procedure for each target energy storage device. The execution cycle is longer than the cycle at which the measurement data is transmitted from the communication device 1. The processing procedure shown in FIG. 5 corresponds to a “creation unit” and a “storage unit”.

The processing unit 20 of the server device 2 reads the measurement data stored in the storage unit 21 in association with the time information for each energy storage cell for a read target period (step S101).

The measurement data is, for example, a voltage value measured in time series. Alternatively, the measurement data may be a voltage value at each time point smoothed by taking a moving average of time-series voltage values. The measurement data may be a graph of the time transition of the voltage value. The measurement data may be a set of a voltage value and a temperature, or a set of a voltage value, a current value, and a temperature. The measurement data is each of a voltage value, a current value, and a temperature, and the model 2M may be created for each data type thereof. The measurement data may be a value calculated using two or three of a voltage value, a current value, and a temperature. The measurement data may be, for example, an SOC value acquired from the management device M (see FIG. 2).

The read target period in step S101 is, for example, a period from the arrival timing of the previous execution cycle to the arrival timing of the current execution cycle. The read target period is determined for each energy storage system 101 in any unit such as one day, one week, two weeks, or one month.

The processing unit 20 groups the read measurement data (step S102), and creates learning data by calculating an average for each group of measurement data (step S103).

In step S103, the processing unit 20 groups the measurement data based on the configuration (hierarchical structure) of the energy storage system 101. For example, the processing unit 20 groups the energy storage cells having the same connection order in the same group among the energy storage cells connected in series included in the power storage modules of the different banks. The processing unit 20 may group the measurement data in banks existing in the same environment (place, building, room, shelf, etc.).

In step S103, the processing unit 20 may create the learning data by other statistical processing instead of the average. The statistical processing may be calculation of a mode value or calculation of a median value.

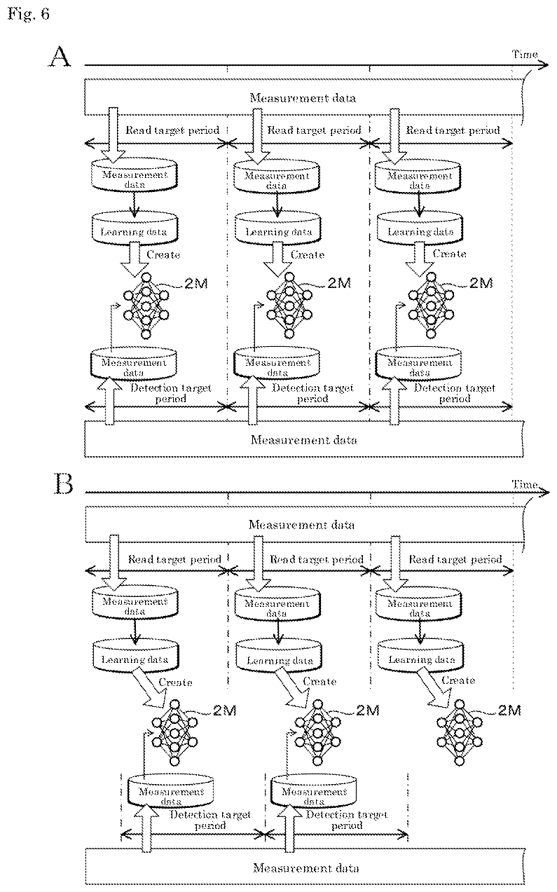

The processing unit 20 creates the model 2M for the measurement data in the detection target period using the created learning data (step S104). The model 2M is learned so as to output a score corresponding to the possibility that the input measurement data includes measurement data of an energy storage cell that is not of the same quality as the learning data (also referred to as abnormality degree and heterogeneity degree) (see FIG. 6).

In step S104, the processing unit 20 learns the learning data (average of the measurement data) created in step S103 as the measurement data (pseudo normal data) of the normal energy storage device.

In the first example, the detection target period in step S104 is a period in which the measurement data is obtained, that is, a period matching the read target period (see FIG. 6A). In the first example, it is determined whether or not the learning data, which is the average of the measurement data, and the individual measurement data are of the same quality. In the second example, the detection target period is a read target period of the measurement data and a period after the read target period (see FIG. 6B). For example, the processing unit 20 may determine, by a model 2M learned from learning data created from measurement data of a certain two weeks, whether or not measurement data measured in a period of two weeks, which is one week after the two weeks and in which one week overlaps, is of the same quality as the learning data.

The processing unit 20 stores the model 2M created in step S104 in the storage unit 21 in association with the identification data (step S105), and ends the creation processing and the storage processing of the model 2M. The identification data in step S105 may be a numerical value indicating the read target period or a serial number.

FIG. 6 is an explanatory diagram of the read target period and the detection target period, and shows that measurement data for the read target period is periodically read in the process of storing the measurement data in time series. FIG. 6A shows a case where a reading target period of measurement data for creating learning data matches a period (detection target period) of measurement data to be detected using the learning data. The learning data is created from the read measurement data, and the model 2M is learned from the created learning data. In FIG. 6A, the model 2M is applied to abnormality detection of measurement data measured in the same period as the measurement data that is the source of the learning data.

As shown in FIG. 6A, when the period of the measurement data of the learning data matches the detection target period in which the model 2M is used, it is possible to eliminate the influence of the difference in the period or environment between the time of learning of the model 2M and the time of abnormality detection using the model 2M.

FIG. 6B shows a case where a reading target period of measurement data for creating learning data and a detection target period of measurement data using the learning data are slightly shifted and used. In FIG. 6B, the model 2M is applied to abnormality detection of measurement data read for a period different from the measurement data that is the source of the learning data.

Under a situation where the environment does not change significantly, for example, within 1 to 2 weeks, or in a case where the energy storage system 101 is stopped, as shown in FIG. 6B, the read target period of the learning data and the detection target period may not necessarily match each other. The abnormality detection may be executed on measurement data in a detection target period of the latest two weeks using the model 2M learned by measurement data in a read target period of two weeks from three weeks ago to one week ago.

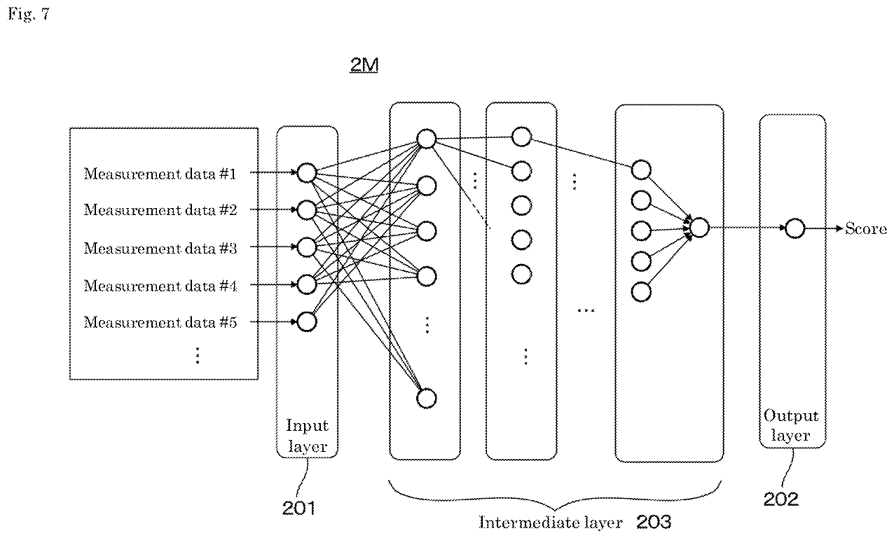

FIG. 7 is a schematic diagram of an example of the model 2M to be created. In one example, the model 2M uses a convolutional neural network, inputs measurement data measured in a plurality of energy storage cells, and outputs a possibility that the input measurement data includes measurement data of heterogeneous energy storage cells. The model 2M may be an auto encoder.

In the example shown in FIG. 7, the model 2M includes an input layer 201 to which measurement data of each of the energy storage cells included in the same module is input. The model 2M includes an output layer 202 that outputs a score based on input measurement data, and an intermediate layer 203 including a convolution layer or a pooling layer. The model 2M is learned by attaching a label indicating that the learning data is not heterogeneous to the learning data created by the averaging and giving the learning data to the neural network. The model 2M outputs, from the output layer 202, a score corresponding to a possibility of including measurement data of an energy storage cell that is not of the same quality.

In another example, the model 2M may be a model that inputs time-series data of measurement data (for example, the voltage value) of the same energy storage cell and outputs a score corresponding to a possibility of including measurement data of heterogeneous energy storage cells. The model 2M may be a classifier that classifies whether or not the input measurement data is measurement data of an abnormal energy storage cell.

According to the design of the model 2M, the number of groups of the measurement data during the read target period in step S102 shown in FIG. 5 is determined. The model 2M shown in FIG. 7 receives voltage values of, for example, twelve energy storage cells included in the module. In step S103 shown in FIG. 5, the processing unit 20 creates a plurality of sets of learning data corresponding to the number of times measured over the read target period, with twelve average values of the voltage values as one set. The number of groups in step S102 may be 12 or a multiple of 12. The groups may be grouped such that the measurement data overlaps each other.

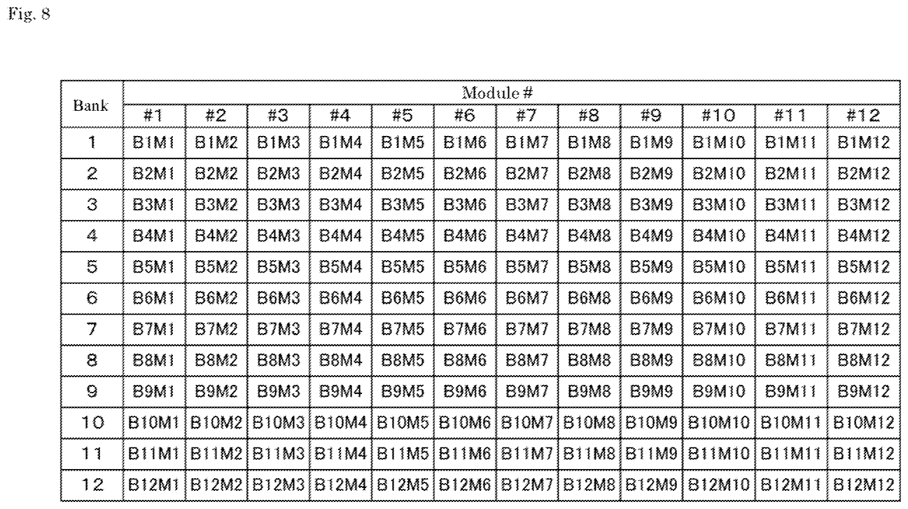

FIG. 8 is a schematic diagram of learning data creation. FIG. 8 shows a table in which identification information (identification number) of modules is represented by a row and a column. Identification information representing a [Y]-th module of an [X]-th bank as B [X] M [Y] is given to each module. In the table of FIG. 7, identification information of one hundred and forty-four modules is shown. Identification information of C [Z] is given to the energy storage cell according to a connection order [Z] in each module. The learning data is created by averaging measurement data of energy storage cells of the same number (connection order) of each module. Measurement data of a [Z]-th energy storage cell of a [Y]-th module of a [X]-th bank is represented as B [X] M [Y] C [Z]. The averaging is performed, for example, as follows.

$$( B 1 M 1 C 1 + B 1 M 2 C 1 + … + B 1 M 12 C 1 + B 2 M1 C 1 + … + B 12 M 12 C 1 ) / 144 \\ ( B 1 M 1 C 2 + B 1 M 2 C 2 + … + B 1 M 12 C 2 + B 2 M 1 C 2 + … + B 12 M 12 C 2 ) / 144 \\ … \\ ( B 1 M 1 C 12 + B 1 M 2 C 12 + … + B 1 M 12 C 12 + B 2 M 1 C 12 + … + B 12 M 12 C 12 ) / 144$$

As described above, the measurement data is averaged with the measurement data of the energy storage cells having the same connection order among the energy storage cells connected in series. Note that, in a case where there is a non-operating bank (inactive bank), measurement data of the non-operating bank is excluded from the target of the averaging.

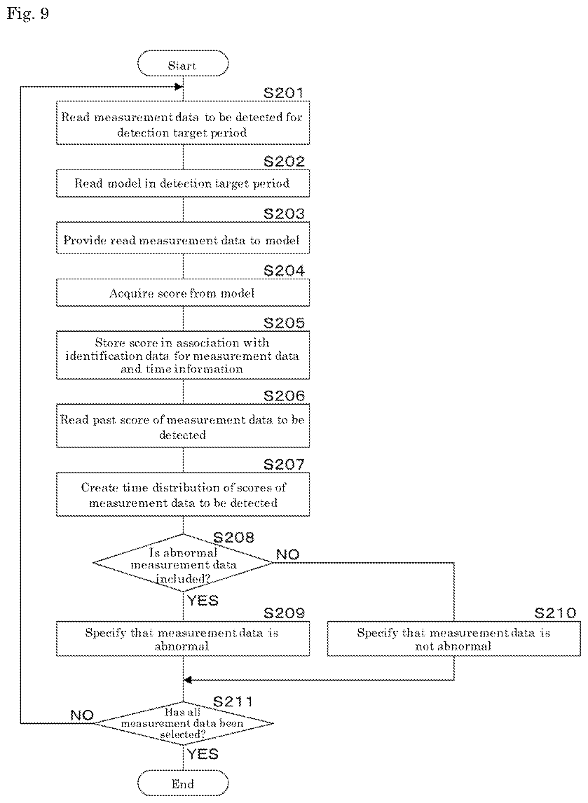

The abnormality detection processing based on the model 2M learned by the created learning data will be described. FIG. 9 is a flowchart showing an example of an abnormality detection processing procedure by the server device 2. The processing unit 20 of the server device 2 executes the following processing at a cycle similar to the execution cycle of the processing procedure of FIG. 5. The processing procedure shown in FIG. 9 corresponds to a “detection unit”.

The processing unit 20 reads measurement data to be detected for a detection target period from measurement data of each energy storage cell associated with time information in the storage unit 21 (step S201). In step S201, the processing unit 20 selects and reads measurement data of energy storage cells included in the same module.

The processing unit 20 reads the model 2M corresponding to the detection target period from the storage unit 21 (step S202). As described above, the model 2M corresponding to the detection target period is the model 2M learned by the measurement data in the read target period matching the detection target period, or the model 2M learned by the measurement data in the read target period partially overlapping the detection target period.

The processing unit 20 provides the measurement data to be detected read in step S201 to the model 2M read in step S202 (step S203). The processing unit 20 acquires a score output from the model 2M (step S204).

In step S203, the processing unit 20 provides measurement data (voltage value) of each of the plurality of energy storage cells included in the same module, and in step S204, acquires a score indicating whether or not measurement data of heterogeneous energy storage cells is included in the measurement data.

The processing unit 20 stores the score acquired in step S203 in the storage unit 21 in association with the identification data for identifying the energy storage cell group of the measurement data to be detected and the time information of the acquired measurement data (step S205).

The processing unit 20 reads the score of the past predetermined time stored in the storage unit 21 for the measurement data to be detected (step S206). The processing unit 20 creates a time distribution of scores for the past predetermined time (step S207).

The processing unit 20 determines whether or not abnormal measurement data is included in the measurement data to be detected based on the time distribution created in step S207 (step S208). In step S208, the processing unit 20 may make a determination by referring to the score acquired in step S204. The processing unit 20 may make a determination by referring to the measurement data itself read in step S201.

When it is determined in step S208 that abnormal measurement data is included (S208: YES), the processing unit 20 specifies that the measurement data to be detected is abnormal (step S209), and advances the processing to step S211.

When it is determined that abnormal measurement data is not included (S208: NO), the processing unit 20 specifies that the measurement data to be detected is not abnormal (step S210), and advances the processing to step S211.

The processing unit 20 determines whether or not all the measurement data has been selected in step S201 (step S211). When it is determined that all the measurement data has not been selected (S211: NO), the processing unit 20 returns the processing to step S201.

When it is determined that all the measurement data has been selected (S211: YES), the processing unit 20 ends the abnormality detection processing.

The processing unit 20 determines whether or not abnormal measurement data is included in each module in which the energy storage cells are connected in series. Alternatively, the unit of the energy storage cell to be detected may be determined according to the design of the model 2M. For example, the determination may be made on a bank basis, or may be made for each energy storage cell.

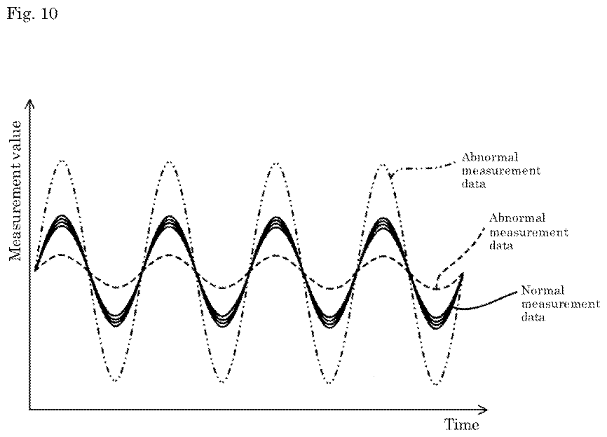

FIG. 10 is a graph schematically showing a time distribution of measurement data of a plurality of energy storage cells. The horizontal axis in FIG. 10 indicates the passage of time. In FIG. 10, the vertical axis represents the magnitude of the value of the measurement data. In the graph of FIG. 10, a curve indicated by a solid line is measurement data of a normal energy storage cell. In the graph of FIG. 10, a curve indicated by a broken line and a curve indicated by a two-dot chain line are measurement data of an abnormal (or heterogeneous) energy storage cell.

As shown in FIG. 10, the measurement data of the abnormal energy storage cell has an excessively large value or an excessively small value as compared with the normal measurement data. The amount of measurement data for an abnormal energy storage cell is very small as compared to the amount of measurement data for a normal energy storage cell. When the measurement data is averaged including these excessively large and excessively small measurement data, it is estimated that the average value is not significantly different from the normal measurement data indicated by the solid line. The learning data of the model 2M used in the abnormality detection method is not labeled as normal data that does not include measurement data of an abnormal energy storage cell or labeled as measurement data of an abnormal energy storage cell.

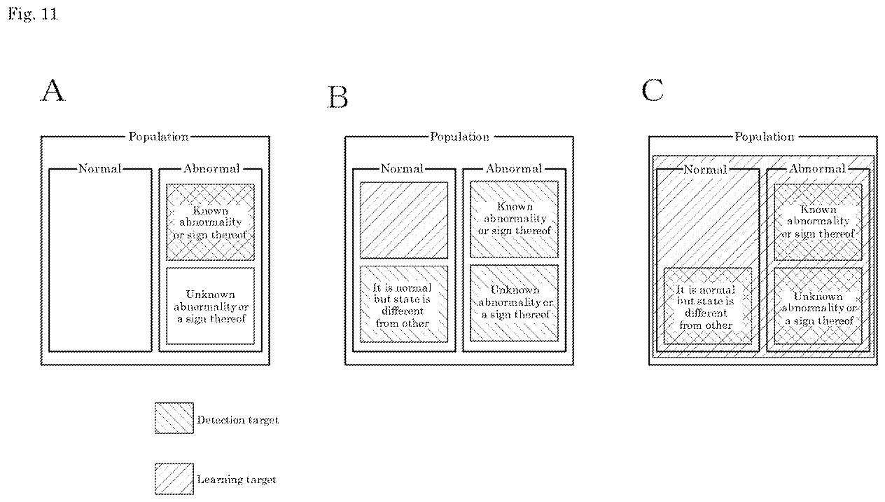

FIG. 11 is a diagram showing an application range of the abnormality detection method. FIG. 11 shows an attribute of a set of measurement data. The measurement data includes measurement data of normal energy storage cells and measurement data of abnormal energy storage cells with respect to the population. The normal energy storage cell includes a standard energy storage cell and an energy storage cell that is normal but different (heterogeneous) from other energy storage cells. The abnormal energy storage cell includes an energy storage cell indicating a known abnormality or sign thereof and an energy storage cell indicating an unknown abnormality or a sign thereof.

In FIG. 11, among the attributes of each piece of measurement data, a data attribute of a learning target and data attribute to be detected by the learned model are indicated by hatching. FIG. 11A shows a learning target and a detection target of a learning model used for conventional abnormality detection. As shown in FIG. 11A, in the conventional abnormality detection, a learned model based on teacher data in which measurement data of a known abnormal energy storage device is labeled as abnormal is used. It is necessary to prepare a sufficient number of abnormality data as learning data. In the conventional abnormality detection, measurement data of a known abnormal energy storage device is detected. In the conventional learned model, measurement data of an energy storage device in which an unknown abnormality appears can be excluded from a detection target of the abnormality. In the energy storage device, there is a possibility that an abnormality of an unknown pattern appears depending on a use environment or a use period. That is, when the energy storage device is used in an environment different from the test process of the energy storage device, an abnormality that cannot be detected by a learning model based on learning data created in advance may occur. It is difficult to distinguish an energy storage cell that may exhibit an abnormality of an unknown pattern before starting operation.

FIG. 11B shows a learning target and a detection target of a learning model in another abnormality detection. In the learning model of FIG. 11B, only data of an energy storage cell having standard characteristics as designed is set as a learning target, and learning is performed so as to detect data having an attribute different from that of the data of the standard energy storage cell. In the case of FIG. 11B, it is determined that the measurement data is abnormal with respect to the measurement data in which the measurement data of the energy storage device having the attribute different from that of the energy storage device to be learned is mixed. In this case, an unknown abnormality or a sign thereof can be detected. However, it is also determined that an energy storage cell that is normal but different (heterogeneous) from other energy storage cells is abnormal. For example, when a new energy storage device is mixed with an energy storage device which has been operated for several years, it is determined that the new energy storage device is abnormal.

FIG. 11C shows a learning target and a detection target of the model 2M of the present embodiment. As shown in FIG. 11C, since the model 2M performs learning by averaging all data including abnormality and normality, it is possible to detect measurement data deviating from an average pattern, and it is also possible to detect heterogeneous measurement data such as measurement data of a new energy storage device. By using the average value as the learning data, it is possible to distinguish the heterogeneity while a certain change (trend) is occurring in the entire energy storage system 101. For example, while the temperature changes due to a change in season, most characteristics of the energy storage cells included in the energy storage system 101 change with certain characteristics due to a change in temperature. Among them, it is possible to extract only heterogeneous energy storage cells or modules that do not follow the trend.

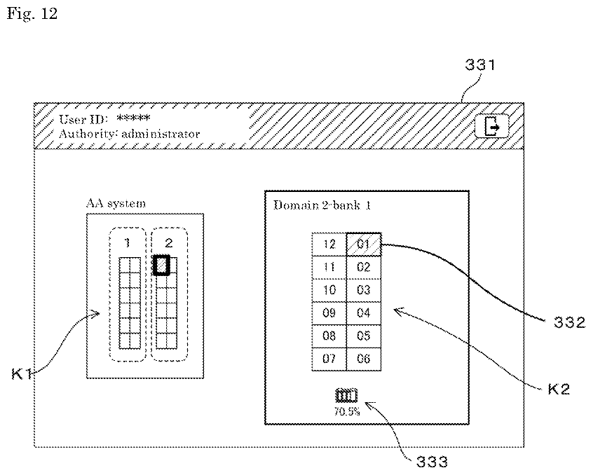

FIG. 12 shows an example of a state screen 331 displayed on the client device 3. The state screen 331 includes an image K1 that visually indicates the configuration of the energy storage system 101. In the image K1, an arrangement of two domains is shown. Each rectangle of the image K1 indicates a bank. In the image K1, a thick frame indicates that the first bank in the domain 2 is selected. The rectangle indicating the bank of the image K1 indicates the presence or absence of abnormality by the color and pattern indicated by hatching. An image K2 indicates the arrangement and state of the modules included in the bank selected in the image K1. Each rectangle of the image K2 indicates a module. The rectangle of the module of the measurement data in which the abnormality is detected is emphasized by an object 332 having a different color or pattern. The state screen 331 includes an object 333 that visually indicates the SOC of the entire selected bank. As described above, the abnormality detected for each energy storage cell and module is visually output by the state screen 331.

The embodiment disclosed as described above is illustrative in all respects and is not restrictive. The scope of the present invention is defined by the claims, and includes meanings equivalent to the claims and all modifications within the scope.

1. An abnormality detection device comprising:
a creation unit that creates learning data by statistically processing plural pieces of measurement data, which may include abnormal measurement data, of an energy storage device;
a storage unit that stores a model learned to output a score corresponding to whether or not abnormal measurement data is included in the measurement data when the measurement data is input using the created learning data; and
a detection unit that detects an abnormality or a sign of abnormality of the energy storage device based on the score output by inputting the plurality of pieces of measurement data to the model.

2. The abnormality detection device according to claim 1, wherein the creation unit creates the learning data using an average of the plural pieces of measurement data which may include abnormal measurement data of the energy storage device.

3. The abnormality detection device according to claim 2, wherein
the energy storage device is configured by connecting plural modules including plural energy storage cells in series, and
the creation unit creates the learning data by averaging measurement data of energy storage cells of same order in the plurality of modules.

4. The abnormality detection device according to claim 2, wherein
in the energy storage device, plural banks in which plural modules including plural energy storage cells are connected in series are connected in parallel to form a domain, and
the creation unit creates the learning data by averaging measurement data of energy storage cells of same order in the plurality of modules included in the domain.

5. The abnormality detection device according to claim 1, wherein
the creation unit creates the learning data from measurement data read for a read target period among measurement data measured in time series from the energy storage device, and
the detection unit inputs, to a model learned by the learning data, measurement data in a detection target period that is a same period as the read target period, and detects an abnormality or a sign of abnormality of the energy storage device in the detection target period based on a score output from the model.

6. The abnormality detection device according to claim 1, wherein
the creation unit creates the learning data from measurement data read for a read target period among measurement data measured in time series from the energy storage device, and
the detection unit inputs, to a model learned by the learning data, measurement data in a detection target period partially overlapping the read target period, and detects an abnormality or a sign of abnormality of the energy storage device in the detection target period based on a score output from the model.

7. An abnormality detection method comprising:
creating learning data by statistically processing plural pieces of measurement data of an energy storage device, the plurality of pieces of measurement data that may include abnormal measurement data;
learning a model to output a score corresponding to whether or not abnormal measurement data is included in the measurement data when the measurement data is input using the created learning data;
storing the learned model; and
detecting an abnormality or a sign of abnormality of the energy storage device based on a score output by inputting the plurality of pieces of measurement data to the model.

8. A computer program that causes a computer to execute processes of:
creating learning data by statistically processing plural pieces of measurement data of an energy storage device, the plurality of pieces of measurement data that may include abnormal measurement data;
learning a model to output a score corresponding to whether or not abnormal measurement data is included in the measurement data when the measurement data is input using the created learning data;
storing the learned model; and
detecting an abnormality or a sign of abnormality of the energy storage device based on a score output by inputting the plurality of pieces of measurement data to the model.
